(19) United States
(12) Patent Application Publication
(10) Pub. No.: US 2024/0412978 A1
(43) Pub. Date: Dec. 12, 2024

(54) GAS TREATMENT METHOD AND GAS TREATMENT DEVICE

(71) Applicant: Tokyo Electron Limited, Minato-ku, Tokyo (JP)

(72) Inventors: Kimihiko DEMICHI, Nirasaki City, Yamanashi (JP); Tetsuro TAKAHASHI, Nirasaki City, Yamanashi (JP); Changhwan SEOK, Icheon-si, Gyeonggi-do (KR); Jun KOBAYASHI, Nirasaki City, Yamanashi (JP); Akihiro SATO, Minato-ku, Tokyo (JP)

(21) Appl. No.: 18/718,981

(22) PCT Filed: Sep. 29, 2022
(86) PCT No.: PCT/JP2022/036408

§ 371 Date: Jun. 12, 2024

(30) Foreign Application Priority Data
Dec. 13, 2021 (JP) 2021-201496

(51) Int. Cl. H01L 21/311; H01L 21/67

(52) U.S. Cl. CPC H01L 21/31116; H01L 21/67069

(57) ABSTRACT

A gas treatment method of performing a gas treatment on a substrate having a recess includes: disposing the substrate having the recess in a chamber; adjusting a pressure inside the chamber to a predetermined pressure by supplying a pressure adjustment gas into the chamber in an evacuated state to increase the pressure inside the chamber; and subsequently, performing the gas treatment on a side wall of the recess of the substrate by causing a treatment reaction by a process gas in the chamber, wherein the process gas causing the treatment reaction is used as at least a part of the pressure adjustment gas in the adjusting the pressure.

### TECHNICAL FIELD

The present disclosure relates to a gas treatment method and a gas treatment device.

### BACKGROUND

In a manufacturing process of a semiconductor device, a technique for performing chemical treatment using a process gas on a semiconductor wafer, which is a substrate, is known. For example, Patent Documents 1 and 2 disclose techniques for etching a silicon oxide film (SiO₂ film) present on a semiconductor wafer using a hydrogen fluoride (HF) gas and an ammonia (NH₃) gas.

### PRIOR ART DOCUMENTS

### Patent Documents

Patent Document 1: Japanese Patent Laid-Open Publication No. 2007-180418
Patent Document 2: Japanese Patent Laid-Open Publication No. 2017-191897

The present disclosure provides a gas treatment method and a gas treatment device that are capable of uniformly performing treatment at a top portion and a bottom portion of a recess in gas treatment of a substrate having the recess with a high aspect ratio.

### SUMMARY

According to one embodiment of the present disclosure, a gas treatment method of performing gas treatment on a substrate having a recess includes disposing the substrate having the recess in a chamber, adjusting a pressure inside the chamber to a predetermined pressure by supplying a pressure adjustment gas into the chamber in an evacuated state to increase the pressure inside the chamber, and subsequently, performing the gas treatment on a side wall of the recess of the substrate by causing a treatment reaction by a process gas in the chamber. The process gas that causes the treatment reaction is used as at least a part of the pressure adjustment gas in the adjusting the pressure.

According to the present disclosure, it is possible to provide a gas treatment method and a gas treatment device that are capable of uniformly performing treatment at a top portion and a bottom portion of a recess in gas treatment of a substrate having the recess with a high aspect ratio.

### BRIEF DESCRIPTION OF DRAWINGS

FIG. 1 is a cross-sectional view showing an example of a gas treatment device for carrying out a gas treatment method according to an embodiment.

FIG. 2 is a cross-sectional view showing an example of a structure of a substrate used in an etching method according to an embodiment.

FIG. 3 is a cross-sectional view showing an etched state of the substrate of FIG. 2.

FIG. 4 is a diagram showing a specific gas supply timing and pressure in the related art.

FIG. 5 is a cross-sectional view showing an etched state when a treatment shown in FIG. 4 is applied to a substrate having a recess with a high aspect ratio.

FIGS. 6A and 6B are diagrams schematically showing a gas supply to a recess in a pressure adjustment step and an etching step when the related art is applied to the substrate having the structure shown in FIG. 2.

FIG. 7 is a diagram showing the amount of a HF gas at a top portion and bottom portion of a recess in an etching step when the related art is applied to the substrate having the structure shown in FIG. 2.

FIG. 8 is a diagram showing a specific gas supply timing and pressure in an example of an embodiment.

FIGS. 9A and 9B are diagrams schematically showing gas supply to a recess in a pressure adjustment step and an etching step when an embodiment is applied to the substrate having the structure shown in FIG. 2.

FIG. 10 is a diagram showing the amount of a HF gas at a top portion and a bottom portion of a recess in an etching step when an embodiment of the present disclosure is applied to the substrate having the structure shown in FIG. 2.

FIG. 11 is a diagram showing an example of a pressure and gas supply sequence in etching according to an embodiment.

FIG. 12 is a diagram showing another example of a pressure and gas supply sequence in etching according to another embodiment.

### DETAILED DESCRIPTION

Embodiments of the present disclosure will now be in detail described in detail with reference to the accompanying drawings.

### <Gas Treatment Device>

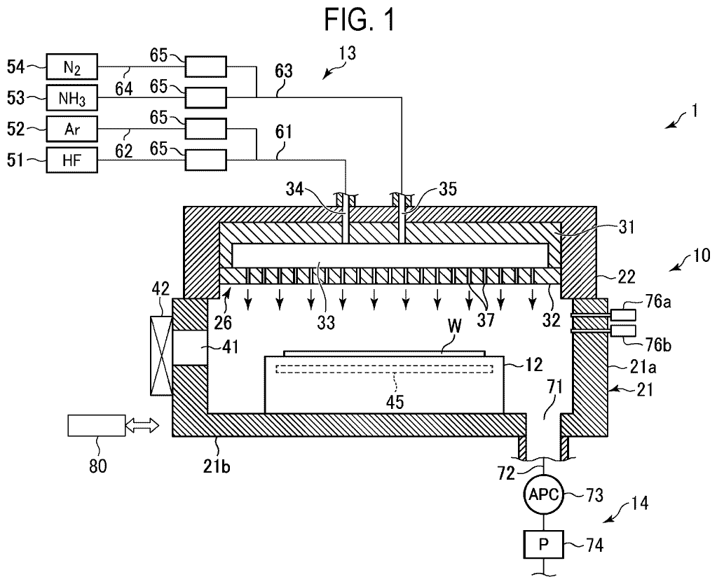

FIG. 1 is a cross-sectional view showing an example of a gas treatment device for carrying out a gas treatment method according to an embodiment. The gas treatment device shown in FIG. 1 is configured as an etching device that etches a silicon oxide-based material present on, for example, a surface of a substrate. A typical example of the silicon oxide-based material is SiO₂. However, SiON, SiOCN, or SiOC may also be used as the silicon oxide-based material.

As shown in FIG. 1, a gas treatment device 1 includes a chamber 10 of a sealed structure, and a stage 12 on which a substrate W is placed in an approximately horizontal state is provided inside the chamber 10. A semiconductor wafer such as a Si wafer is exemplified as the substrate W, but the substrate W is not limited thereto.

The gas treatment device 1 also includes a gas supplier 13 that supplies a process gas to the chamber 10 and an exhauster 14 that exhausts an inside of the chamber 10.

The chamber 10 is composed of a chamber body 21 and a lid portion 22. The chamber body 21 has an approximately cylindrical side wall portion 21a and a bottom portion 21b, and an upper portion of the chamber body 21 has an opening. The opening is closed by the lid portion 22 having a recess therein. The side wall portion 21a and the lid portion 22 are sealed by a sealing member (not shown) to ensure airtightness within the chamber 10.

A shower head 26, which is a gas introduction member, is fitted inside the lid portion 22 so as to face the stage 12. The shower head 26 includes a cylindrical main body 31 having a side wall and an upper wall, and a shower plate 32 installed at a bottom of the main body 31. An outer periphery of the main body 31 and the shower plate 32 are sealed by a seal ring (not shown) to form a sealed structure. In addition, a space 33 for diffusing a gas is formed between a central portion of the main body 31 and the shower plate 32.

A first gas introduction hole 34 and a second gas introduction hole 35 are vertically formed in a ceiling wall of the lid portion 22, and the first gas introduction hole 34 and second gas introduction hole 35 are connected to the space 33 by penetrating through the upper wall of the shower head 26. Gas discharge holes 37 that extend vertically from the space 33 and penetrate through the shower plate 32 to face the inside of the chamber 10 are formed in the shower plate 32.

Therefore, in the shower head 26, gases are supplied to the space 33 from the first gas introduction hole 34 and the second gas introduction hole 35, and a gas mixed in the space 33 is discharged through the gas discharge holes 37.

A loading/unloading port 41 for loading/unloading the substrate W is provided in the side wall portion 21a of the chamber body 21. This loading/unloading port 41 is configured to be openable and closeable by a gate valve 42, thereby allowing the substrate W to be transferred to and from another adjacent module.

The stage 12 has an approximately circular shape when viewed in a plan view and is fixed to the bottom portion 21b of the chamber 10. A temperature adjustor 45 that adjusts the temperature of the stage 12 is installed inside the stage 12. The temperature adjustor 45 is configurable with, for example, a resistance heater, or a temperature adjustment medium flow path through which a temperature adjustment medium (e.g., water) for temperature adjustment is circulated. The temperature adjustor 45 adjusts the temperature of the stage 12 to a desired temperature, thereby adjusting the temperature of the substrate W placed on the stage 12.

The gas supplier 13 has a HF gas supply source 51, an Ar gas supply source 52, an NH₃ gas supply source 53, and an N₂ gas supply source 54.

The HF gas supply source 51 supplies a HF gas as a fluorine-containing gas. Here, the HF gas is exemplified as the fluorine-containing gas, but a F₂ gas, a ClF₃ gas, or a NF₃ gas may also be used as the fluorine-containing gas in addition to the HF gas.

The NH₃ gas supply source 53 supplies an NH₃ gas as a basic gas. Here, the NH₃ gas is exemplified as the basic gas, but an amine gas may also be used as the basic gas in addition to the NH₃ gas. Examples of amine may include methylamine, dimethylamine, and trimethylamine.

The Ar gas supply source 52 and the N₂ gas supply source 54 supply a N₂ gas and an Ar gas as inert gases that have functions of a dilution gas, a purge gas, and a carrier gas. However, both the Ar gas supply source 52 and the N₂ gas supply source 54 may supply the Ar gas or the N₂ gas. Further, the inert gases are not limited to the Ar gas and the N₂ gas, and other noble gases such as a He gas may also be used.

One ends of first to fourth gas supply pipes 61 to 64 are connected to the gas supply sources 51 to 54, respectively. The other end of the first gas supply pipe 61 connected to the HF gas supply source 51 is connected to the first gas introduction hole 34. The other end of the second gas supply pipe 62 connected to the Ar gas supply source 52 is connected to the first gas supply pipe 61. The other end of the third gas supply pipe 63 connected to the NH₃ gas supply source 53 is connected to the second gas introduction hole 35. The other end of the fourth gas supply pipe 64 connected to the N₂ gas supply source 54 is connected to the third gas supply pipe 63.

The HF gas, which is a fluorine-containing gas, and the NH₃ gas, which is a basic gas, reach the shower head 26 together with the Ar gas and the N₂ gas, which are inert gases, through the first gas introduction hole 34 and the second gas introduction hole 35, respectively, and are discharged into the chamber 10 from the gas discharge holes 37 of the shower head 26.

The first to fourth gas supply pipes 61 to 64 are provided with flow rate controllers 65 that open and close flow paths and control flow rates. Each of the flow rate controllers 65 includes, for example, an opening/closing valve, and a flow controller such as a mass flow controller (MFC) or a flow control system (FCS).

The exhauster 14 has an exhaust pipe 72 connected to an exhaust port 71 formed in the bottom portion 21b of the chamber 10 and further includes an automatic pressure control (APC) valve 73 for controlling pressure inside the chamber 10, provided in the exhaust pipe 72, and a vacuum pump 74 for evacuating the inside of the chamber 10.

Two capacitance manometers 76a and 76b for high pressure and low pressure are installed on the side wall of the chamber 10 to control the pressure inside the chamber 10. A temperature sensor (not shown) for detecting the temperature of the substrate W is installed in a vicinity of the substrate W placed on the stage 12.

The chamber 10, the shower head 26, and the stage 12 that constitute the gas treatment device 1 are made of a metal material such as aluminum. A film such as an oxide film may be formed on the surfaces of the chamber 10, the shower head 26, and the stage 12. For example, in the case of aluminum, an anodic oxide film (Al₂O₃) may be used as the film. A ceramic coating may also be used as the film.

The gas treatment device 1 further includes a controller 80. The controller 80 is composed of a computer and includes a main controller including a central processing unit (CPU), an input device, an output device, a display device, and a storage device (storage medium). The main controller controls operation of each component of the gas treatment device 1. Control of each component by the main controller is performed based on a control program stored in the storage medium (a hard disk, an optical disc, a semiconductor memory, etc.) built into the storage device. A processing recipe is stored in the storage medium as the control program, and processing of the gas treatment device 1 is executed based on the processing recipe.

### <Gas Treatment Method>

Next, an embodiment of a gas treatment method performed in the above-mentioned gas treatment device 1 will be described. In the embodiment, the case is exemplarily described in which etching, specifically, etching of a film made of a silicon oxide-based material, is performed as gas treatment on the substrate W having a recess with a high aspect ratio.

A description will be given in detail below. First, the substrate W having the recess with a high aspect ratio is loaded into the chamber 10 and placed on the stage 12. At this time, the temperature of the stage 12 is adjusted the temperature adjustor 45. Then, as a preparatory process, the pressure inside the chamber 10 is raised to about 266.6 Pa (2 Torr) to stabilize the temperature of the substrate W, and then the inside of the chamber 10 is evacuated.

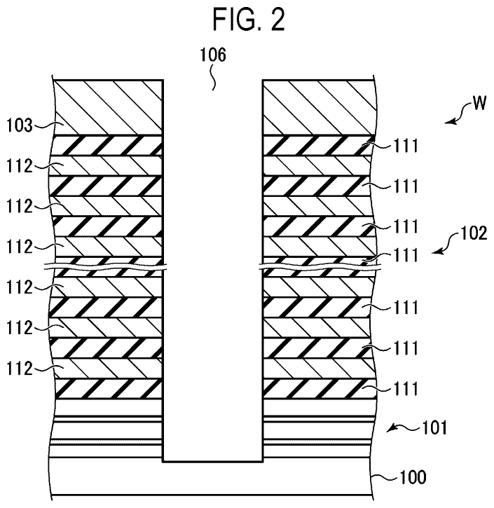

The aspect ratio of the recess of the substrate W is desirably 25 or more. The substrate W having the recess with such a high aspect ratio is used, for example, in a 3D-NAND type nonvolatile semiconductor device. FIG. 2 is a cross-sectional view showing an example of the structure of such a substrate W. In this example, the substrate W includes a lower structure 101 formed on a silicon substrate 100, an ONON (oxide/nitride/oxide/nitride) stacked structure portion 102 formed on the lower structure 101 by alternately stacking SiO₂ film 111 and SiN film 112 multiple times, and an upper structure 103 formed on the ONON stacked structure portion 102. A hole 106 is formed in the upper structure 103, the ONON stacked structure portion 102, and the lower structure 101 so as to penetrate through the upper structure 103, the ONON stacked structure portion 102, and the lower structure 101 in a stacked direction.

Next, a gas is supplied into the evacuated chamber 10 to increase the pressure inside the chamber 10. Thus, the pressure is adjusted to a predetermined set pressure, and the chamber 10 is stabilized at that pressure (a pressure adjustment step).

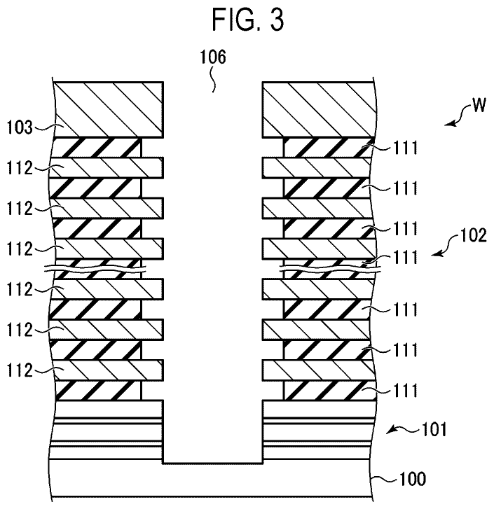

Next, at that pressure, an etching, which is a gas treatment, is performed using an NH₃ gas, which is a basic gas, and a HF gas, which is a fluorine-containing gas (an etching step). In this etching, the silicon oxide-based material present on the sidewall portion of the recess is etched. In the example of FIG. 2, the SiO₂ films 111 of the ONON stacked structure portion 102 present on a sidewall of the hole 106, which is the recess, are etched as shown in FIG. 3.

An etching reaction, which is a treatment reaction in this case, is a reaction between the fluorine-containing gas, the basic gas, and the SiO₂ films 111. In this example, the HF gas, the NH₃ gas, the SiO₂ films 111 react to generate ammonium fluorosilicate (AFS). AFS can be sublimated by setting the temperature of the substrate W to be high.

After performing such etching treatment for a predetermined time, the chamber 10 is evacuated to purge the inside of the chamber 10 (an evacuation step). As a result, a residual gas such as sublimated AFS is discharged from the chamber 10.

While such a sequence may be performed once to perform a desired etching amount, the sequence may be repeated multiple times to perform the desired etching amount. That is, the sequence is repeated multiple times, such as pressure adjustment→etching→evacuation→pressure adjustment→etching→evacuation→ . . . . This allows etching to be performed with better controllability.

However, in the related art, since the purpose of the pressure adjustment step is to achieve stabilization at a treatment pressure, the pressure adjustment step generally does not generate an intended treatment reaction. For example, in Patent Document 2, when etching a SiO₂ film using the HF gas and the NH₃ gas, in a pressure stabilization step, which is the pressure adjustment step, no etching reaction (treatment reaction) occurs by introducing only an Ar gas, a N₂ gas, and an NH₃ gas. Then, in a substrate processing process, the HF gas is introduced for the first time to cause the etching reaction.

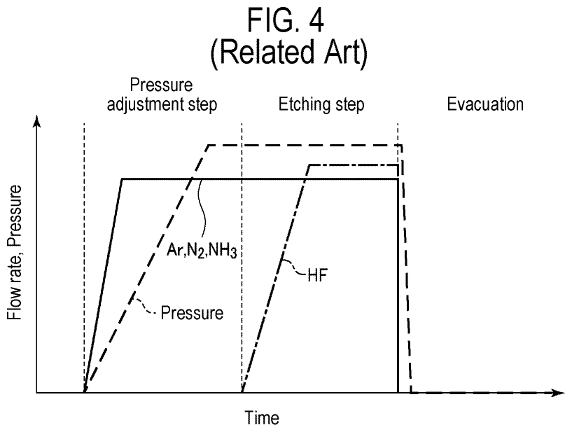

FIG. 4 is a diagram showing a specific gas supply timing and pressure in the related art. As shown in FIG. 4, in the pressure adjustment step, the Ar gas, the N₂ gas, and the NH₃ gas are supplied as pressure adjustment gases into the chamber in the evacuated state to increase the pressure inside the chamber and stabilize the chamber at a set pressure. In the etching step, the HF gas is supplied into the chamber while maintaining the pressure inside the chamber at the set pressure to cause the etching reaction. After a predetermined etching time has elapsed, the supply of the Ar gas, the N₂ gas, the NH₃ gas, and the HF gas is stopped, and the chamber is evacuated.

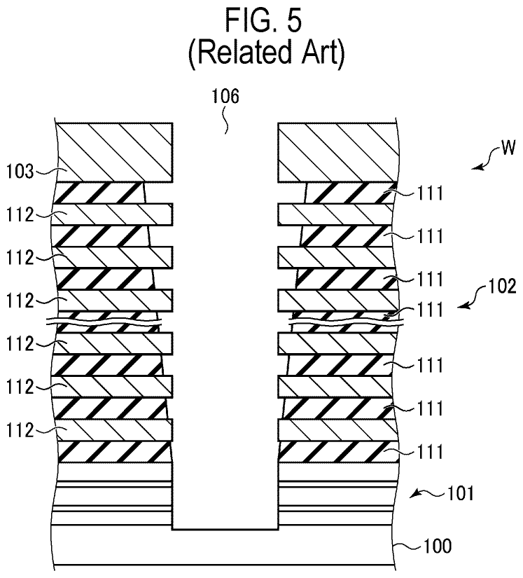

However, when the process of the related art shown in FIG. 4 is applied to a substrate having a recess with a high aspect ratio, it was found that top-bottom loading has occurred, in which the etching amount is smaller at a bottom portion of the recess than at a top portion of the recess. Specifically, in the example of the substrate in FIG. 2, as shown in FIG. 5, the etching amount of the SiO₂ film 111 at the top portion is large, and the etching amount of the SiO₂ film 111 at the bottom portion is small.

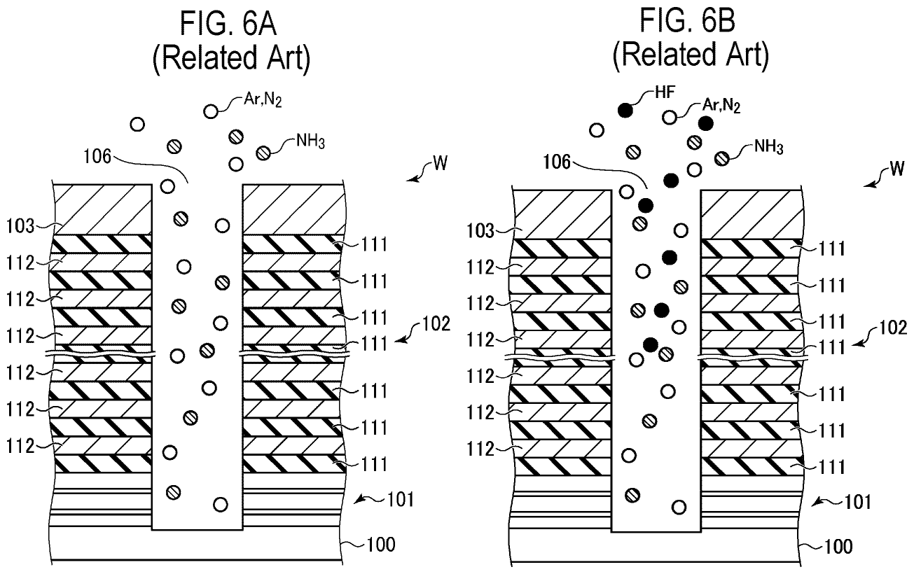

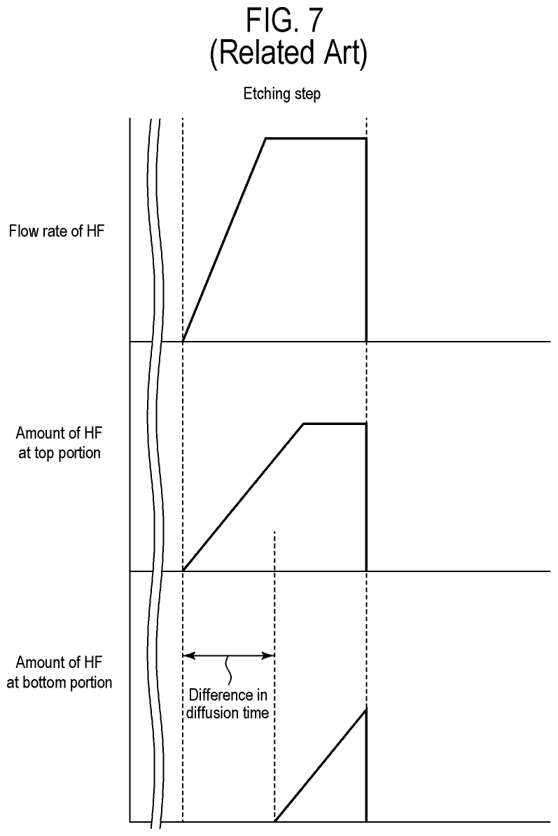

When the Ar gas, the N₂ gas, and the NH₃ gas are supplied into the chamber 10 as pressure adjustment gases so as not to cause the etching reaction in the substrate W having the structure shown in FIG. 2, these gases also exist within the hole 106 as shown in FIG. 6A. Therefore, when the HF gas is supplied for etching after pressure adjustment, diffusion of the HF gas is inhibited by the Ar gas, the N₂ gas, and the NH₃ gas in the hole 106, as shown in FIG. 6B, thereby making it difficult for the HF gas to reach the bottom portion of the hole 106. In other words, as shown in FIG. 7, a diffusion timing of the HF gas corresponding to a part of an etchant becomes slower at the bottom portion than at the top portion, and the amount of the HF gas is also smaller at the bottom portion than at the top portion. This is considered to be the reason why top-bottom loading of the etching step occurs.

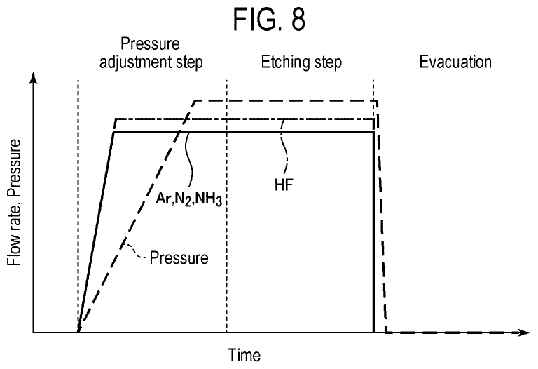

Therefore, in the embodiment, in the pressure adjustment step, not only the Ar gas, the N₂ gas, and the NH₃ gas but also the HF gas is supplied into the chamber 10 as pressure adjustment gases. That is, as a part of the pressure adjustment gases, both the NH₃ gas and the HF gas, which are process gases that cause the etching reaction corresponding to the treatment reaction, are supplied. FIG. 8 is a diagram showing a specific gas supply timing and pressure in an example of an embodiment. As shown in FIG. 8, in this example, in the pressure adjustment step, the HF gas as well as the Ar gas, the N₂ gas, and the NH₃ gas is supplied as the pressure adjustment gases into the evacuated chamber to increase the pressure inside the chamber and stabilize the chamber at a set pressure. Then, the etching step is performed while maintaining the supply of these gases and maintaining the pressure inside the chamber at the set pressure.

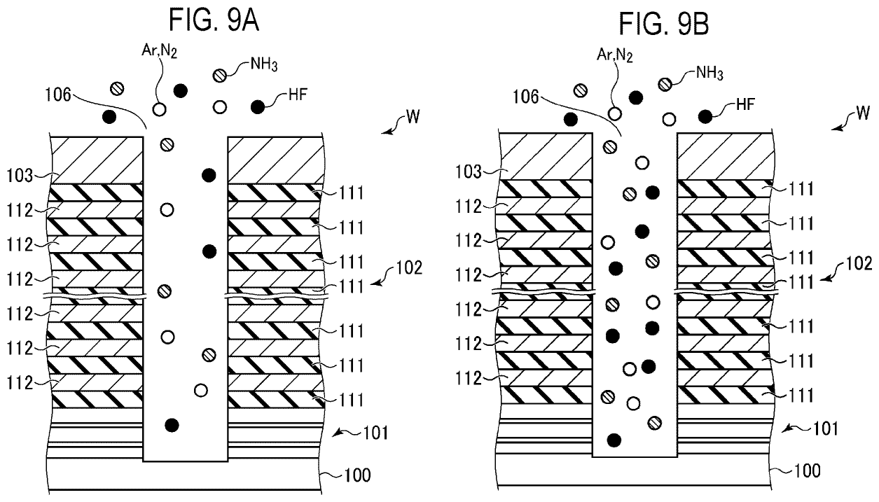

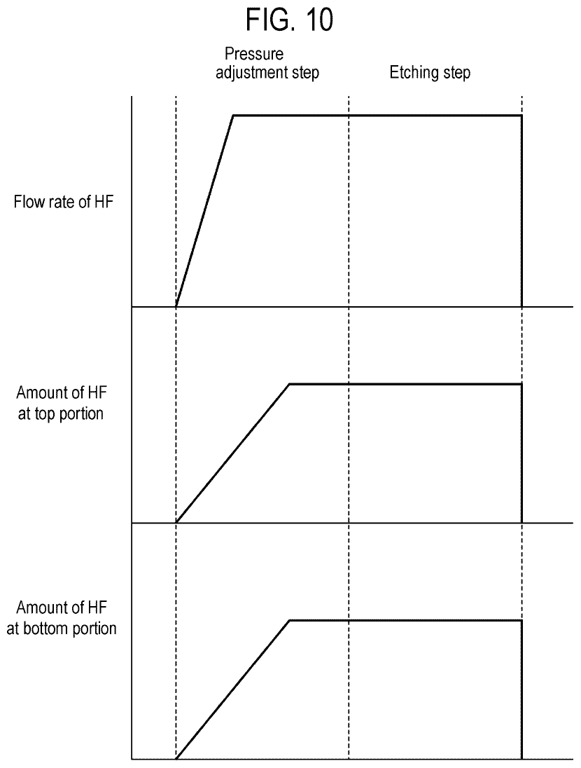

Thereby, as shown in FIG. 9A, the HF gas is introduced into the hole 106 together with the Ar gas, the N₂ gas, and the NH₃ gas. Then, as shown in FIG. 9B, the HF gas is diffused into the bottom portion of the hole 106 almost unhindered by the Ar gas, the N₂ gas, and the NH₃ gas. That is, as shown in FIG. 10, an arrival timing and the amount of the HF gas corresponding to an etchant are approximately the same at the top portion and at the bottom portion, thereby making it possible to perform uniform etching with suppressed top-bottom loading.

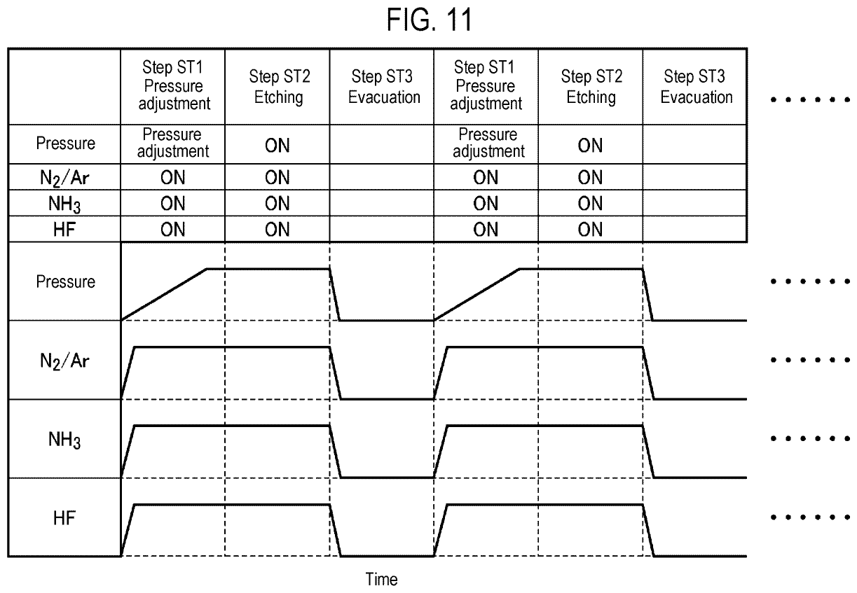

Next, an example of a sequence when performing etching of an embodiment on the substrate W having the structure shown in FIG. 2 will be described. FIG. 11 is a diagram showing an example of a pressure and gas supply sequence in etching according to an embodiment.

In a state in which the substrate is placed on the stage 12, first, the Ar gas, the N₂ gas, the NH₃ gas, and the HF gas are all introduced to increase the pressure inside the chamber 10 and stabilize the chamber at a set pressure (step ST1; pressure adjustment step). Next, the SiO₂ film 111 is etched through the hole 106 while maintaining flow rates of the Ar gas, the N₂ gas, the NH₃ gas, and the HF gas and maintaining the pressure inside the chamber 10 (step ST2; etching step). After the etching step is ended, the chamber 10 is evacuated to purge the inside of the chamber 10 (step ST3; evacuation step). The above steps ST1 to ST3 are repeated a desired number of times.

In the embodiment, since the HF gas is supplied in the pressure adjustment step of step ST1, etching is started at a timing when the pressure in the pressure adjustment step becomes equal to or higher than pressure at which the etching reaction as described above proceeds. That is, the etching reaction progresses before reaching the etching step (step ST2) of a recipe. This can be managed by presetting a time of the etching step (step ST2) in consideration of the etching amount in the pressure adjustment step. In addition, the pressure adjustment step can be integrated into the etching step of the recipe.

In the etching step (step ST2), the temperature of the substrate is desirably in a range of 75 degrees C. to 150 degrees C. Thereby, AFS generated in the etching reaction can be sublimed. The pressure during etching is desirably in a range of 26.6 Pa to 400 Pa (0.2 Torr to 3.0 Torr).

Furthermore, flow rates of the Ar gas, the N₂ gas, the NH₃ gas, and the HF gas are desirably in ranges of 0 sccm to 200 sccm, 0 sccm to 200 sccm, 200 sccm to 1000 sccm, and 200 sccm to 1000 sccm, respectively.

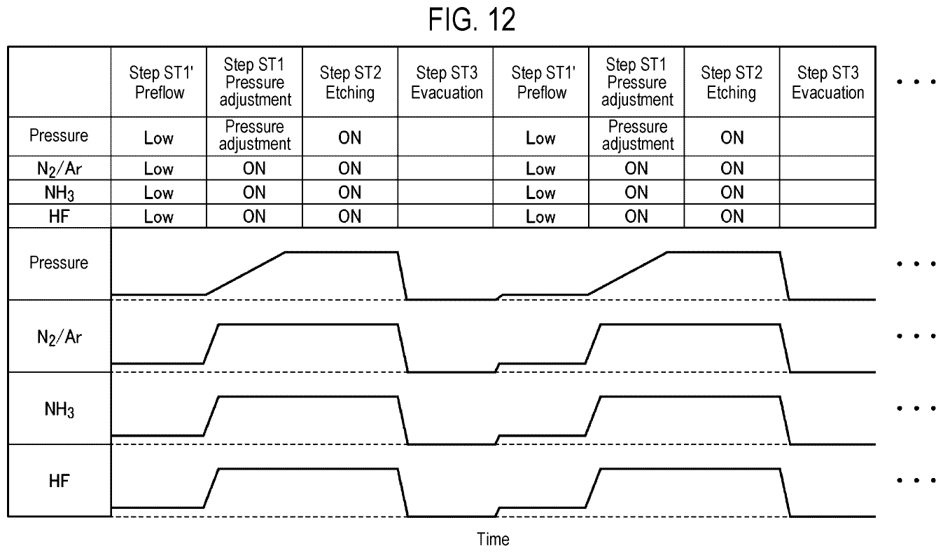

While the above example shows that the Ar gas, the N₂ gas, the NH₃ gas, and the HF gas are all supplied from the beginning in the pressure adjustment step, the gases may be preflowed (step ST1′), as shown in FIG. 12, in a range that does not affect etching. While FIG. 12 shows an example in which all gases are preflowed, some gases (e.g., the N₂ gas and the Ar gas, or the N₂ gas, the Ar gas, and the NH₃ gas) may be preflowed.

In addition, while the above example shows that the sequence of sublimating the generated AFS at a high treatment temperature and discharging the sublimated AFS by evacuation is repeated, the treatment temperature may be a low temperature ranging from 10 degrees C. to 75 degrees C., for example, 35 degrees C. In this case, after treatment with the NH₃ gas and the HF gas, the heat treatment is performed in another chamber to sublimate the AFS. These processes are performed once or multiple times.

If the HF gas is supplied in the pressure adjustment step to the substrate W having the recess with a high aspect ratio as in the embodiment, the concentration of the HF gas at the bottom portion of the recess increases during etching, and thus etching may be bottom-first. In such a case, uniformity can be achieved by adjusting parameters such as pressure.

### Experiment Example

Next, an experimental example will be described. Herein, the SiO₂ film has been etched on the substrate having the structure shown in FIG. 2 by the device shown in FIG. 1 using the NH₃ gas and the HF gas as etching gases (etchants). Etching conditions include a substrate temperature of 80 degrees C. to 100 degrees C., a pressure of 53.3 Pa to 106.6 Pa (0.4 Torr to 0.8 Torr), a flow rate of the NH₃ gas of 250 sccm to 800 sccm, and a flow rate of the HF gas of 250 sccm to 800 sccm, a flow rate of the Ar gas of 50 sccm to 150 sccm, and a flow rate of the N₂ gas of 50 sccm to 150 sccm.

Under the above conditions, etching has been performed by a sequence in the related art (sequence A) in which the HF gas is not supplied in the pressure adjustment step and a sequence of the embodiment (sequence B) in which the HF gas is supplied in the pressure adjustment step. In sequence A, a cycle including the pressure adjustment→the etching→the evacuation has been performed 9 times with an etching time of 3 sec and an evacuation time of 60 sec. In sequence B, a cycle including the pressure adjustment→the etching→the evacuation has been performed 6 times with an etching time of 0.5 sec and an evacuation time of 60 sec. After etching, an etching amount, and a loading value expressed as “minimum etching amount (Min)/maximum etching amount (Max)×100” in the hole have been determined. As a result, sequence A was top-first (the etching amount of the recess is larger in the upper portion than in the bottom portion) with an etching amount of 12.6 nm and a loading value of 61.3%. On the other hand, sequence B was top-first with an etching amount of 9.2 nm and a loading value of 87.9%, thereby confirming that top-bottom loading has been improved using the method of the embodiment.

### Other Applications

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the accompanying claims and the spirit of the disclosure.

For example, while the above embodiment has described an example in which the silicon oxide-based material is etched using the NH₃ gas and the HF gas, the present disclosure is not limited thereto and can be similarly applied to the case in which etching is performed using other gases.

In addition, while an example in which the NH₃ gas and the HF gas, which are process gases that cause an etching reaction corresponding to a treatment reaction, are used, and the N₂ gas and the Ar gas, which are inert gases, are used, as part of the pressure adjustment gases, has been described, the pressure adjustment gases may be only the process gases that cause the treatment reaction. That is, the process gases that cause the treatment reaction may be used as at least a part of the pressure adjustment gases.

Further, while the above embodiment has described an example in which the substrate has the ONON stacked structure portion in which an SiO₂ film and an SiN film are alternately stacked multiple times and has the hole as a recess in a stacked direction, the present disclosure is not limited thereto. For example, the substrate may be a substrate in which an etching target film is uniformly formed on a side surface of the recess with a high aspect ratio.

Furthermore, gas treatment is not limited to the etching and may be other gas treatment such as a chemical vapor deposition (CVD) film formation. Even in the case of other gas treatment, top-bottom loading of treatment can be suppressed by supplying the process gas that causes the treatment reaction from the pressure adjustment step to the substrate having the recess with a high aspect ratio.

Furthermore, while the above embodiment has described an example in which the semiconductor wafer is used as the substrate, the present disclosure is not limited to the semiconductor wafer, and other substrates such as a flat panel display (FPD) substrate, which is a representative substrate for a liquid crystal display (LCD) substrate, and a ceramic substrate may be used.

### EXPLANATION OF REFERENCE NUMERALS

1: gas treatment device, 10: chamber, 12: stage, 13: gas supplier, 14: exhauster, 26: shower head, 45: temperature adjustor, 51: HF gas supply source, 53: NH₃ gas supply source, 80: controller, 100: silicon substrate. 102: ONON stacked structure portion, 106: hole (recess), 111: SiO₂ film, W: substrate

1. A gas treatment method of performing a gas treatment on a substrate having a recess, the gas treatment method comprising:
disposing the substrate having the recess in a chamber;
adjusting a pressure inside the chamber to a predetermined pressure by supplying a pressure adjustment gas into the chamber in an evacuated state to increase the pressure inside the chamber; and
subsequently, performing the gas treatment on a side wall of the recess of the substrate by causing a treatment reaction by a process gas in the chamber,
wherein the process gas causing the treatment reaction is used as at least a part of the pressure adjustment gas in the adjusting the pressure.

2. The gas treatment method of claim 1, wherein an aspect ratio of the recess of the substrate is 25 or more.

3. The gas treatment method of claim 1, wherein the gas treatment is an etching.

4. The gas treatment method of claim 3, wherein the process gas includes a basic gas and a fluorine-containing gas, and etches a silicon oxide-based material present on the side wall of the recess of the substrate.

5. The gas treatment method of claim 4, wherein the substrate includes a stacked structure portion formed by alternately stacking an SiO₂ film, which is the silicon oxide-based material, and an SiN film multiple times, and includes a hole as the recess formed in a stacked direction of the stacked structure portion, and
wherein in the performing the gas treatment, the SiO₂ film present on the side wall of the hole is etched.

6. The gas treatment method of claim 4, wherein the pressure adjustment gas in the adjusting the pressure further includes an inert gas, in addition to the basic gas and the fluorine-containing gas as the process gas.

7. The gas treatment method of claim 6, wherein the basic gas and the fluorine-containing gas, as the process gas, and the inert gas are supplied in the adjusting the pressure and are continuously supplied in the performing the gas treatment.

8. The gas treatment method of claim 7, wherein the basic gas is an NH₃ gas and the fluorine-containing gas is a HF gas.

9. The gas treatment method of claim 7, further comprising evacuating an interior of the chamber after the performing the gas treatment, wherein the adjusting the pressure, the performing the gas treatment, and the evacuating the interior of the chamber are repeated multiple times.

10. A gas treatment device for performing a gas treatment on a substrate having a recess, the gas treatment device comprising:
a chamber configured to accommodate the substrate having the recess;
a stage disposed in the chamber and configured to place the substrate on the stage;
a gas supplier configured to supply a gas into the chamber;
an exhauster configured to exhaust an interior of the chamber; and
a controller,
wherein the controller is configured to execute:
disposing the substrate in the chamber;
adjusting a pressure inside the chamber to a predetermined pressure by supplying a pressure adjustment gas into the chamber in an evacuated state to increase the pressure inside the chamber; and
subsequently, performing the gas treatment on a side wall of the recess of the substrate by causing a treatment reaction by a process gas in the chamber, and
wherein the controller is configured to perform a control such that the process gas causing the treatment reaction is used as at least a part of the pressure adjustment gas in the adjusting the pressure.

11. The gas treatment device of claim 10, wherein an aspect ratio of the recess of the substrate is 25 or more.

12. The gas treatment device of claim 10, wherein the gas treatment is an etching.

13. The gas treatment device of claim 12, wherein the process gas includes a basic gas and a fluorine-containing gas, and etches a silicon oxide-based material present on the side wall of the recess of the substrate.

14. The gas treatment device of claim 13, wherein the controller is configured to control the gas supplier such that the pressure adjustment gas in the adjusting the pressure further includes an inert gas, in addition to the basic gas and the fluorine-containing gas as the process gas.

15. The gas treatment device of claim 14, wherein the controller is configured to control the gas supplier such that the basic gas and the fluorine-containing gas, as the process gas, and the inert gas are supplied in the adjusting the pressure and are continuously supplied in the performing the gas treatment.

16. The gas treatment device of claim 15, wherein the basic gas is an NH₃ gas and the fluorine-containing gas is a HF gas.

17. The gas treatment device of claim 15, wherein the controller is further configured to execute evacuating the interior of the chamber after the performing the gas treatment and is configured to perform control such that the adjusting the pressure, the performing the gas treatment, and the evacuating the interior of the chamber are repeated multiple times.

18. A gas treatment method of performing a gas treatment on a substrate having a recess, the gas treatment method comprising:
disposing the substrate having the recess in a chamber;
adjusting a pressure inside the chamber to a predetermined pressure by supplying a pressure adjustment gas into the chamber in an evacuated state to increase the pressure inside the chamber;
subsequently, performing the gas treatment on a side wall of the recess of the substrate by causing a treatment reaction by a process gas in the chamber; and
evacuating an interior of the chamber after the performing the gas treatment, wherein the process gas causing the treatment reaction is used as at least a part of the pressure adjustment gas in the adjusting the pressure,
wherein the adjusting the pressure, the performing the gas treatment, and the evacuating the interior of the chamber are repeated multiple times, and
wherein in the performing the gas treatment, a temperature of the substrate is in a range of 75 degrees C. to 150 degrees C.
